(19) United States
(12) Patent Application Publication
(10) Pub. No.: US 2026/0157153 A1
(43) Pub. Date: Jun. 4, 2026

(54) APPARATUSES AND METHODS FOR ETCHING PROCESS

(71) Applicant: Tokyo Electron Limited, Tokyo (JP)

(72) Inventors: Sean Patrick Berglund, Austin, TX (US); Kate Abel, Austin, TX (US); Ihsan Simms, Austin, TX (US); Michael Carcasi, Austin, TX (US)

(21) Appl. No.: 18/965,934

(22) Filed: Dec. 2, 2024

(51) Int. Cl. H01L 21/66; H01L 21/306; H01L 21/67; H01L 21/683

(52) U.S. Cl. CPC H10P 74/207; H10P 50/646; H10P 72/06; H10P 72/78; H10P 74/203

(57) ABSTRACT

A method is provided for an etching process. The method includes dispensing a liquid electrolyte layer over a layer-to-be-etched on a substrate. A first electrode is coupled to the substrate, and a second electrode is coupled to the liquid electrolyte layer. An alternating voltage is applied at different frequencies between these electrodes. Impedance data is collected in response to the alternating voltage. The etching process is then performed with an etching parameter selected based on the collected impedance data, allowing for precise control and improved uniformity of the layer-to-be-etched.

### TECHNICAL FIELD

The present invention relates generally to semiconductor manufacturing process, and, in particular embodiments, to methods and apparatuses used for etching process.

### BACKGROUND

In semiconductor manufacturing, deposited thin films often exhibit non-uniform radial distribution of thickness, which can directly impact subsequent processes and potentially lead to device defects or failures. Surface preparation tools are employed to enhance film uniformity through precise etching processes. These tools dispense wet etchants over the thin film to selectively react with and dissolve targeted materials. By controlling the composition and dispensing position of the wet etchant, the thickness of the thin film can be selectively adjusted to achieve the desired radial distribution. This approach improves the uniformity of the deposited thin film, leading to higher yield rate during semiconductor manufacturing and enhancing overall device performance and reliability.

### SUMMARY

In accordance with one aspect of the present invention, a method is provided for an etching process. The method comprises dispensing a liquid electrolyte layer over a layer-to-be-etched disposed over a substrate, coupling a first electrode to the substrate and a second electrode to the liquid electrolyte layer, applying an alternating voltage at different frequencies between the first and the second electrodes, collecting impedance data between the first and the second electrodes in response to the alternating voltage, and etching the layer-to-be-etched with an etching parameter selected based on the impedance data.

In accordance with another aspect of the present invention, a method is provided for an etching process. The method comprises dispensing a first liquid electrolyte droplet over a layer-to-be-etched disposed over a substrate, coupling a first electrode to the first liquid electrolyte droplet, dispensing a second liquid electrolyte droplet over the layer-to-be-etched, wherein the second liquid electrolyte droplet remains isolated from the first liquid electrolyte droplet, coupling a second electrode to the second liquid electrolyte droplet, applying an alternating voltage at different frequencies between the first and the second electrodes, collecting impedance data between the first and the second electrodes in response to the alternating voltage, and etching the layer-to-be-etched with an etching parameter selected based on the impedance data.

In accordance with another aspect of the present invention, an etching apparatus is provided. The apparatus comprises an etch chamber, a dispensing arm disposed within the etch chamber, the dispensing arm configured to dispense a first liquid electrolyte layer over a layer-to-be-etched of a substrate, a first electrode configured to be coupled to the substrate, a second electrode configured to be coupled to the first liquid electrolyte layer, and an impedance spectroscope coupled to the first and the second electrodes, the impedance spectroscope being configured to apply an alternating voltage at different frequencies between the first and the second electrodes to collect impedance data.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a flowchart illustrating a method for an etching process, in accordance with some embodiments;

FIGS. 2A-2B are schematic views of an apparatus for an etching process, in accordance with various embodiments;

FIG. 3A is an enlarged schematic view of an apparatus of FIG. 2B, and FIG. 3B is a corresponding equivalent electrical circuit model of FIG. 3A, in accordance with an embodiment;

FIG. 4 is a schematic Nyquist plot of the equivalent electrical circuit model of FIG. 3B, in accordance with an embodiment;

FIG. 5A is an enlarged schematic view of a variation of the apparatus in FIG. 2A, and FIG. 5B is a corresponding equivalent electrical circuit model of FIG. 5A, in accordance with an embodiment;

FIGS. 6A-6B are schematic Nyquist plots of the equivalent electrical circuit model of FIG. 5B, in accordance with an embodiment;

FIG. 7 is an enlarged schematic view of a variation of the apparatus in FIG. 2A, in accordance with an embodiment;

FIG. 8 is an enlarged schematic view of a variation of the apparatus in FIG. 2A, in accordance with an embodiment;

FIG. 9 is an enlarged schematic view of a variation of the apparatus in FIG. 2A, in accordance with an embodiment;

FIG. 10A is an enlarged schematic view of a variation of the apparatus in FIG. 2A, and FIG. 10B is a corresponding equivalent electrical circuit model of FIG. 10A, in accordance with an embodiment;

FIG. 11 is a schematic Nyquist plot of the equivalent electrical circuit model of FIG. 10B, in accordance with an embodiment;

FIGS. 12A-12B are schematic plots of impedance changes in response to different layer thickness changes, in accordance with an embodiment;

FIG. 13 is an enlarged schematic view of a variation of the apparatus in FIG. 2A, in accordance with an embodiment;

FIG. 14A is an enlarged schematic view of a variation of the apparatus in FIG. 2A, and FIG. 14B is a corresponding equivalent electrical circuit model of FIG. 14A, in accordance with an embodiment;

FIG. 15A is an enlarged schematic view of a variation of the apparatus in FIG. 2A, and FIG. 15B is a corresponding equivalent electrical circuit model of FIG. 15A, in accordance with an embodiment;

### DETAILED DESCRIPTION OF ILLUSTRATIVE EMBODIMENTS

Etching processes in surface preparation involve dispensing wet etchants over thin films to selectively dissolve targeted materials, achieving a more uniform distribution of thickness. Precision in this process relies on controlling rates of etching and wet etchant compositions at different radial positions, which may change during the process. Adjusting etching parameters such as duration, temperature, and wet etchant dispensing location can enhance precision. However, conventional etching processes lack the ability to monitor these changes in real-time, limiting efficiency and achievable uniformity.

Real-time measurements of thin film thickness, rates of etching and wet etchant compositions at different radial positions can be beneficial for improving etching precision. Access to this detailed information may enable dynamic and immediate adjustments of the etching parameters to correct any possible deviation, enhancing etching uniformity.

Embodiments of this application describe structures and methods to measure, in real-time, the thickness of thin film and wet etchant composition that enable immediate adjustments over etching parameters for improved etching uniformity. Additionally, in various embodiments, the method can determine the thickness of a thin film in a local location and adjust etching parameters for the entire thin film to address wafer-to-wafer variation. Such measurements are enabled by real-time impedance analysis over the thin film as will be described in more detail below.

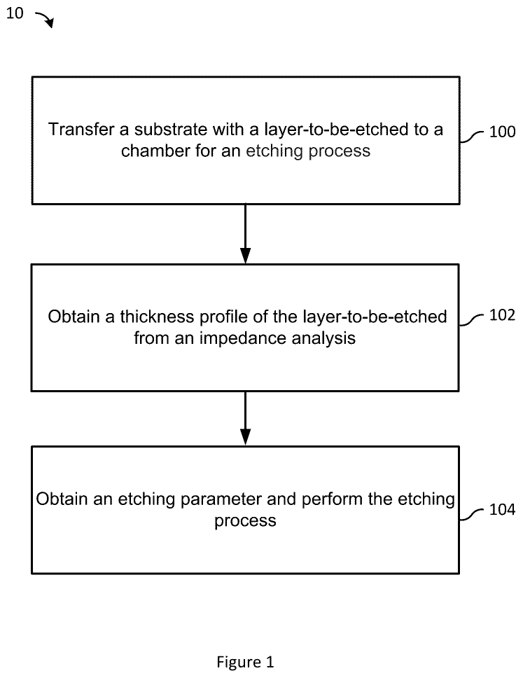

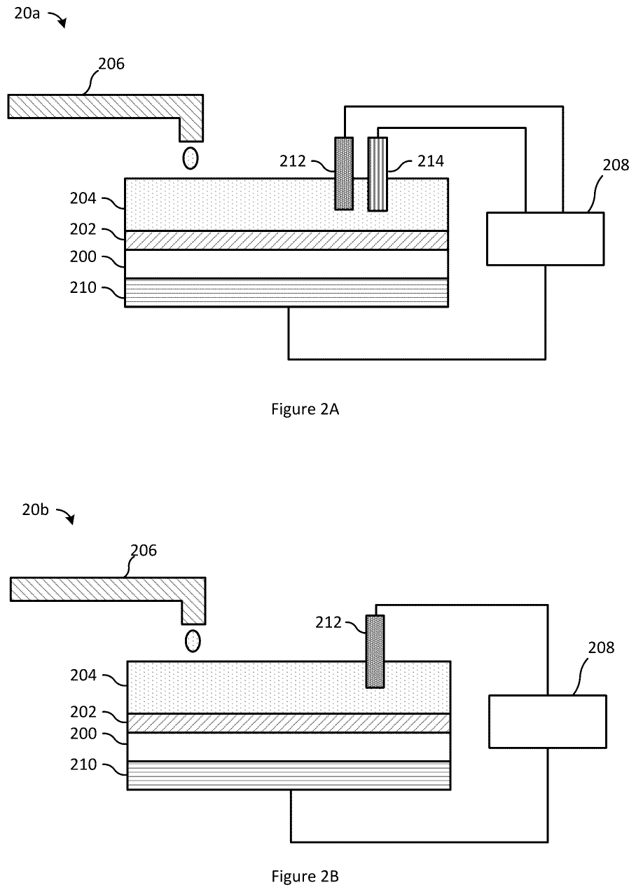

An embodiment generic method will first be described using FIG. 1. Various embodiments of an apparatus for an etching process will be described using FIGS. 2A-2B, 5, 7-10, 13-15. Various embodiment methods will be described while describing the respective apparatus.

FIG. 1 is a flow chart illustrating a method 10 for etching the thin film, also referred to below as a layer-to-be-etched, formed on a substrate, in accordance with some embodiments.

The method may begin with operation 100 in which the substrate is transferred into a chamber for the etching process. The chamber may be configured for any suitable etching technique comprising usage of wet etchant such as hydrofluoric acid (HF), sulfuric acid (H₂SO₄), phosphoric acid (H₃PO₄), ethylenediamine pyrocatechol (EDP), tetramethylammonium hydroxide (TMAH), nitric acid (HNO₃), hydrochloric acid (HCl), hydrobromic acid (HBr), peroxymonosulfuric acid (H₂SO₅), acetic acid, citric acid, hydrogen peroxide (H₂O₂), potassium hydroxide (KOH), ammonium hydroxide (NH₄OH), or the like. In some embodiments, the chamber may provide a controlled environment for material removal from the substrate. The chamber wall may comprise a lining material such as corrosion-resistant materials resistant to the etch chemistry, such as polytetrafluoroethylene (PTFE), polypropylene, fluorinated ethylene propylene, ethylene chlorotrifluoroethylene, polyvinylidene fluoride, polyvinyl chloride, perfluoroalkoxy, ceramic materials such as alumina or silicon carbide, quartz, or stainless steel. The chamber may be coupled to a precise temperature control system to ensure real-time temperature adjustment to change the rate of etching, and a dispensing arm to dispense wet etchant or other liquid electrolyte onto a specific position of the substrate. The etching chamber may also comprise ventilation and exhaust systems to safely manage fumes and vapors.

The method 10 may proceed with operation 102 in which a thickness profile of the layer-to-be-etched may be obtained. The thickness profile may comprise a radial distribution of the thickness of the layer-to-be-etched across the substrate. Changes in the thickness may affect the capacitive and resistive behaviors associated with the layer-to-be-etched, which may be accurately measured by an impedance spectroscope, as described in further detail below. The rate of etching of the layer-to-be-etched may further be obtained by analyzing the thickness over an etching duration. The impedance analysis may enable thickness measurement with high resolution of 0.5 nm to 5 nm.

The method 10 may further proceed with operation 104 in which the etching parameter may be obtained based on the thickness profile to perform or adjust the etching process. The etching parameter may comprise etching chamber temperature, wet etchant composition, etching duration, or position of a dispensing arm that is configured to dispense wet etchant. The measurement of the thickness of the layer-to-be-etched through impedance analysis may take place during the etching process, allowing for real-time thickness monitoring and providing feedback to adjust the etching parameter. In some embodiments, an additional cleaning step may be applied after etching process to remove the etchant on the layer-to-be-etched or any liquid electrolyte that was used for electrochemical measurements.

In some embodiments, a real-time measurement of the impedance of the wet etchant may be performed to determine wet etchant composition during the etching process. This may allow for real-time chemical monitoring and providing feedback to adjust any possible deviation in chemical composition. This dynamic adjustment of etching parameters in response to the real-time impedance measurement may enhance the etching process control for optimal etching uniformity with precise specifications.

FIG. 2A is a schematic view of an apparatus for the etching process, in accordance with some embodiments. The apparatus 20a may comprise a substrate 200, a layer-to-be-etched 202 disposed over the substrate 200, a liquid electrolyte layer 204, a first electrode 210, a second electrode 212, a third electrode 214, an impedance spectroscope 208, and a dispensing arm 206.

The substrate 200 may comprise a bulk substrate such as a blank silicon wafer, a silicon-on-insulator (SOI) wafer, or any of various other semiconductor substrates. The substrate 200 may also be coated or layered with any number of additional materials, including compound semiconductors, metal or metal oxides, or metal nitrides. The substrate 200 may include any material portion or structure of a device, particularly a semiconductor or other electronics device. The substrate 200 may serve as a foundation for the layer-to-be-etched 202 which is the subject of thickness profile measurement. The layer-to-be-etched 202 may comprise group 3-5 semiconductors, metals, oxides, carbides, nitrides, polymers, or any other materials suitable for etching.

The first liquid electrolyte layer 204 may be dispensed over the layer-to-be-etched 202 and comprise water, isopropyl alcohol, ammonium halides and carbonates in water that are less reactive with the layer-to-be-etched 202, but high enough conductivities for electrochemical measurements. The ammonium halides and carbonates may comprise ammonium chloride (NH₄Cl), ammonium fluoride (NH₄F), ammonium iodide (NH₄I), ammonium sulfate ((NH₄)₂SO₄), ammonium carbonate ((NH₄)₂CO₃), or ammonium bicarbonate ((NH₄)HCO₃).

In some embodiments, the first liquid electrolyte layer 204 may further comprise non-aqueous solvents such as methanol, ethanol, isopropanol, acetone, ethyl acetate, acetonitrile, ketones, dimethyl sulfoxide (DMSO), or the like, to adjust the reactivity between the first liquid electrolyte layer 204 and the layer-to-be-etched 202. In one example, tetramethylammonium hydroxide (TMAH) may be mixed with methanol. In another example, hydrochloric acid (HCl), hydrofluoric acid (HF), hydrobromic acid (HBr), or hydroiodic acid (HI) may be mixed with methanol. In another example, ammonium chloride (NH₄Cl) may be mixed with acetone or ethyl acetate. In another example, ammonium tetrafluoroborate (NH₄BF₄) may be mixed with non-aqueous solvents such as methanol, isopropanol, ethanol, or the like. The first liquid electrolyte layer 204 may be removed before the wet etchant is dispensed over the layer-to-be-etched 202 for etching process.

In some embodiments, the first liquid electrolyte layer 204 may comprise ionic liquids such as 1-ethyl-3-methylimidazolium dicyanamide, 1-ethyl-3-methylimdazolium thiocyanate, 1-ethyl-3-methylimidazolium tetrafluoroborate, 1-ethyl-3-methylimidazolium trifluoromethylsulfonate, or the like. The ionic liquid exhibits advantage of negligible vapor pressure, minimizing evaporation during impedance measurements. Additionally, its relatively high conductivity and broad stability range are particularly beneficial for ensuring reliable impedance measurements.

In some embodiments, the first liquid electrolyte layer 204 may comprise existing wet etchant on the layer-to-be-etched 202 without additional electrolyte solution, to streamline the procedure. The wet etchant may comprise hydrofluoric acid (HF), sulfuric acid (H₂SO₄), phosphoric acid (H₃PO₄), ethylenediamine pyrocatechol (EDP), tetramethylammonium hydroxide (TMAH), nitric acid (HNO₃), hydrochloric acid (HCl), peroxymonosulfuric acid (H₂SO₅), acetic acid, citric acid, hydrogen peroxide (H₂O₂), potassium hydroxide (KOH), ammonium hydroxide (NH₄OH), or the like.

The dispensing arm 206 may be lined with/made with corrosion-resistant materials such as polytetrafluoroethylene (PTFE), polypropylene, fluorinated ethylene propylene, ethylene chlorotrifluoroethylene, polyvinylidene fluoride, polyvinyl chloride, perfluoroalkoxy, ceramic materials such as alumina or silicon carbide, quartz, or stainless steel. The dispensing arm 206 may move to adjust local chemical compositions in specific areas of the first liquid electrolyte layer 204, thereby improving radial etching uniformity.

The first electrode 210 may be coupled to the substrate 200 and function as a working electrode. It may comprise inert conductive materials such as platinum, gold, glassy carbon, carbon paste, or the like. In some embodiments, the first electrode 210 may be the chuck or the substrate holder during processing.

The second electrode 212 may comprise inert materials such as platinum, graphite, gold, or the like, and may be coupled to the first liquid electrolyte layer 204. The second electrode may function as a counter electrode, providing current flow pathway and completing the necessary electrical circuit with the first electrode 210. To improve coupling to the first liquid electrolyte layer 204, the second electrode 212 may have a high surface area.

The third electrode 214 may function as a reference electrode, providing a reference potential for voltage measurement accuracy with minimal current flow. The third electrode 214 may comprise silver/silver chloride (Ag/AgCl), calomel, or mercury/mercury sulfate. To minimize current flow and prevent interference with the reference potential measurement, the distance between the third electrode 214 and the second electrode 212 may be adequately maintained. The optimal distance may be determined by adjusting the position of the third electrode 214 until a stable reference potential is achieved. In some embodiments, the distance may be 1 cm to 5 cm for accurate potential measurement.

The impedance spectroscope 208 may control input electrical parameters such as voltage, current, or frequency being applied at the first and the second electrodes 210, 212 and collect output response from the first, the second, and the third electrodes 210, 212, and 214 for impedance analysis. The impedance spectroscope 208 may comprise a potentiostat or a frequency response analyzer (FRA) to supply an alternating voltage at different frequencies and measure the frequency-dependent impedance.

Based on the impedance data, the thickness of the layer-to-be-etched 202 may be obtained, from which the rate of etching may be derived to determine if the etching parameters require adjustments for improved uniformity. The etching parameters may comprise etching chamber temperature, wet etchant composition, etching duration, or dispensing arm position. The integration of impedance analysis may add a metrology function to the conventional etching process, thereby enhancing etching performance. The impedance measurement can determine the thickness of the layer-to-be-etched 202 in a local location which is used to adjust etching parameters for the entire layer to address the problem of wafer-to-wafer variation. This approach allows for broader process control and consistency across multiple wafers.

FIG. 2B is a schematic view of an apparatus variation with reference to FIG. 2A, in accordance to some embodiments. The apparatus 20b may eliminate the third electrode 214 which may serve as the reference electrode, from the apparatus 20a illustrated in FIG. 2A. The reference electrode may not be needed during impedance measurement since the absolute electrochemical potential of the layer-to-be-etched 202 may not be used to obtain the thickness. By eliminating the third electrode 214, the apparatus 20b may have improved design flexibility with reduced complexity and lower materials cost, leading to more affordable end-user pricing. Moreover, this may reduce the maintenance demands arising from some sensitive internal components of the reference electrode. For example, an Ag/AgCl electrode may contain a potassium chloride electrolyte solution that needs to remain stable for accurate measurements. Over time, this electrolyte may evaporate or become contaminated, necessitating replenishment or replacement to maintain performance.

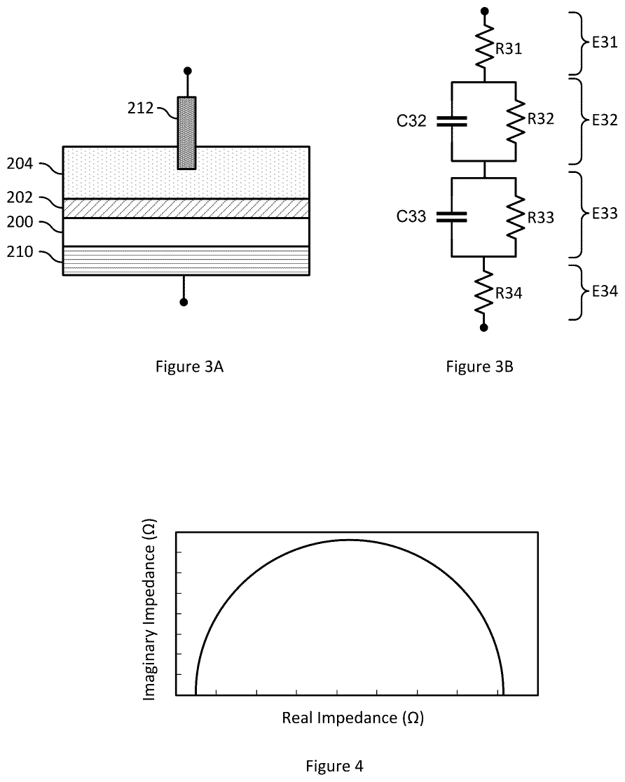

FIG. 3A is an enlarged schematic view of the apparatus 20b illustrated in FIG. 2B, in accordance to an embodiment.

The layer-to-be-etched 202 may be disposed over the substrate 200. The first liquid electrolyte layer 204 may be dispensed over the layer-to-be-etched 202 to serve as a charge carrier medium. The first electrode 210 may be coupled to the substrate 200 while the second electrode 212 may be coupled to the first liquid electrolyte layer 204. The components in FIG. 3A may respectively comprise the materials, structures, and/or other components described above with reference to corresponding parts of FIGS. 2A-2B.

In some embodiments, an alternating voltage at different frequencies may be applied between the first electrode 210 (serving as the working electrode) and the second electrode 212 (serving as the counter electrode) from the impedance spectroscope 208. A complete electrical circuit may be formed with current flowing through the first electrode 210, the substrate 200, the layer-to-be-etched 202, the first liquid electrolyte layer 204, and the second electrode 212.

The current response to the alternating voltage provides insight into the impedance of the electrical circuit, relating to its resistance and capacitance. The impedance may be a frequency-dependent complex quantity, representing both a real impedance and an imaginary impedance. A non-ideal capacitor, whose impedance may not behave ideally as an ideal capacitor may be referred as a constant phase element (CPE). The impedance of a capacitor or a CPE is typically expressed as:

$$Z = \frac{1}{{( j 2 π f )}^{α} Q} \qquad ( Equation 1 )$$

where Z is the impedance of the capacitor or CPE, f is the frequency in units of Hz, j is an imaginary unit. α is a fit parameter. When α=1, the element is an ideal capacitor, and when 0<α<1, the element is a CPE. Q may be another fit parameter with units of capacitance. The measured impedance may be plotted vs. frequency in a Nyquist plot. Resistance and capacitance values of each element (resistor, capacitor or CPE) in an equivalent electrical circuit model may be obtained by fitting the Equation 1 to the Nyquist plot. The thickness of the layer-to-be-etched 202 may affect its impedance that is associated with its interface with another layer. By collecting the impedance of the layer-to-be-etched 202 during the etching process, the real-time thickness and rate of etching may be determined.

FIG. 3B shows a corresponding equivalent electrical circuit model of FIG. 3A, in accordance with one embodiment. The equivalent electrical circuit model may be represented by a series connection of four electrical elements E31-E34. Resistance R31 may represent the resistance of a first element E31 comprising the first liquid electrolyte layer 204.

Resistance R32 and capacitance C32 may collectively represent the impedance of a second element E32 comprising an interface between the first liquid electrolyte layer 204 and the layer-to-be-etched 202. This interface may have a resistive behavior (giving rise to the resistance R32) due to current flow and a capacitive behavior (giving rise to the capacitance C32) due to charge storage at the interface.

Resistance R33 and capacitance C33 may collectively represent the impedance of a third element E33 comprising an interface between the layer-to-be-etched 202 and the substrate 200. This interface may also have a resistive behavior (giving rise to the resistance R33) due to electron flow and a capacitive behavior (giving rise to the capacitance C33) due to charge storage at the interface.

Resistance R34 may represent the resistance of a fourth element E34 comprising the substrate 200. In some embodiments, the substrate 200 may comprise conductive materials and therefore the resistance R34 may be minimal compared to resistances R31-R33.

Referring to FIG. 4, a schematic Nyquist plot of the equivalent electrical circuit model with reference to FIG. 3B is shown, in accordance with an embodiment.

The Nyquist plot displays the measured impedance against frequency and features a semicircular curve. The Nyquist plot may be fitted using Equation 1 to calculate the capacitances and resistances of the first, the second, the third, and the fourth elements E31-E34 with reference to FIG. 3B.

A database correlating impedance data of the layer-to-be-etched 202 in different thicknesses may be pretested and constructed. Therefore, the measured impedance of the layer-to-be-etched 202 may be used to obtain the corresponding thickness by referencing this database. In some embodiments, the impedance measurement may be performed in-situ with the etching process. Along with a reduction of the thickness of the layer-to-be-etched 202 during the etching process, a variation of impedance data may be collected in real time. This information may be used to determine the real-time rate of etching. If the thickness or the rate of etching deviates from desired specifications, the etching parameters may be adjusted accordingly, optimizing the etching process. This approach may enable real-time etching adjustments for improved precision and consistency.

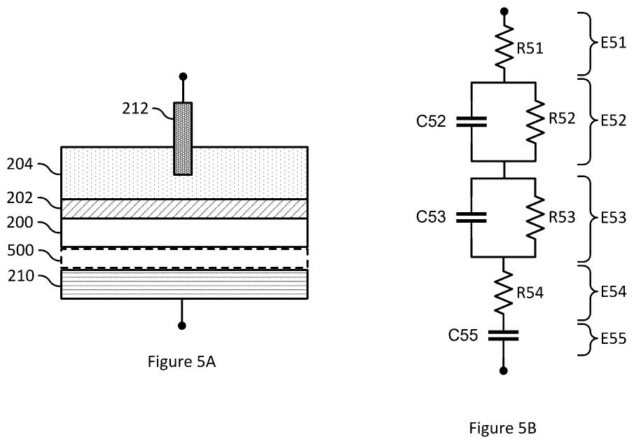

FIG. 5A shows an enlarged schematic view of a variation of the apparatus 20a illustrated in FIG. 2A, in accordance with an embodiment. The embodiment differs from the prior embodiments by including a gap 500 between the substrate 200 and the first electrode 210. The layer-to-be-etched 202 may be disposed over the substrate 200. The first liquid electrolyte layer 204 may be dispensed over the layer-to-be-etched 202 and serve as a charge carrier medium.

In some embodiments, the first electrode 210 may be coupled to the substrate 200 through the gap 500 comprising air or vacuum. The gap 500 may arise from a vacuum chuck used to hold the substrate 200 in place. The gap 500 may also be intentionally created by separating the substrate 200 from the first electrode 210. By preventing direct contact between the first electrode 210 and the substrate 200, the gap 500 may help avoid potential mechanical scratching or particle contamination of the substrate 200. The incorporation of the gap 500 may contribute to maintaining the integrity of the substrate 200 during etching processing. The second electrode 212 may be coupled to the first liquid electrolyte layer 204 to complete the electrical circuit. The components in FIG. 5A may respectively comprise the materials, structures, and/or other components described above with reference to corresponding parts of FIGS. 2A-2B.

FIG. 5B shows a corresponding equivalent electrical circuit model with reference to FIG. 5A, in accordance with an embodiment. The equivalent electrical circuit model may be represented by a series connection of five electrical elements E51-E55. Resistance R51 may represent the resistance of a first element E51 comprising the first liquid electrolyte layer 204.

Resistance R52 and capacitance C52 may collectively represent the impedance of a second element E52 comprising the interface between the first liquid electrolyte layer 204 and the layer-to-be-etched 202. This interface may have a resistive behavior (giving rise to the resistance R52) due to current flow and a capacitive behavior (giving rise to the capacitance C52) due to charge storage at the interface.

Resistance R53 and capacitance C53 may collectively represent the impedance of a third element E53 comprising the interface between the layer-to-be-etched 202 and the substrate 200. This interface may also have a resistive behavior (giving rise to the resistance R53) due to electron flow and a capacitive behavior (giving rise to the capacitance C53) due to charge storage at the interface.

Resistance R54 may represent the resistance of a fourth element E54 comprising the substrate 200. Capacitance C55 may represent the capacitance of a fifth element E55, comprising the capacitor formed by the substrate 200 and the first electrode 210 with the incorporation of the gap 500.

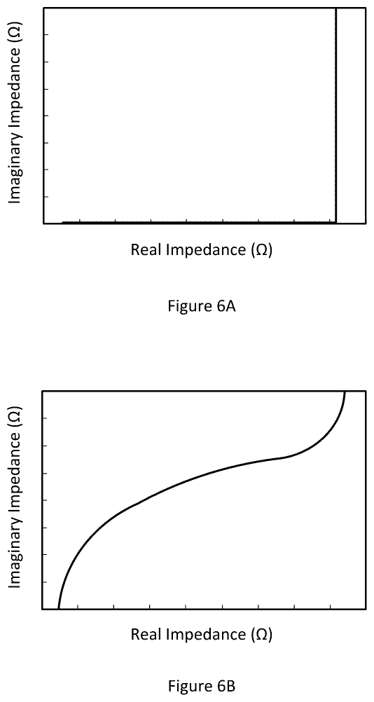

FIG. 6A presents a schematic Nyquist plot reflecting the equivalent electrical circuit model with reference to FIG. 5B, in accordance with an embodiment. The capacitor effect introduced by the gap 500 may cause a spike in the imaginary impedance at a high-value region of the real impedance. This phenomenon may be indicative of a high capacitance C55 resulting from the separation between the first electrode 210 and the substrate 200.

FIG. 6B is a zoomed-in view of the Nyquist plot depicted in FIG. 6A, focusing on a lower-value region of the imaginary impedance. In this detailed section, the Nyquist plot may exhibit a quarter-circle curve. This curve may be fitted using Equation 1, providing precise calculations of the capacitance and resistance for each electrical element in FIG. 5B. The incorporation of the gap 500 may help prevent mechanical damage and contamination to the substrate 200 without sacrificing the capability to measure the impedance of the layer-to-be-etched 202.

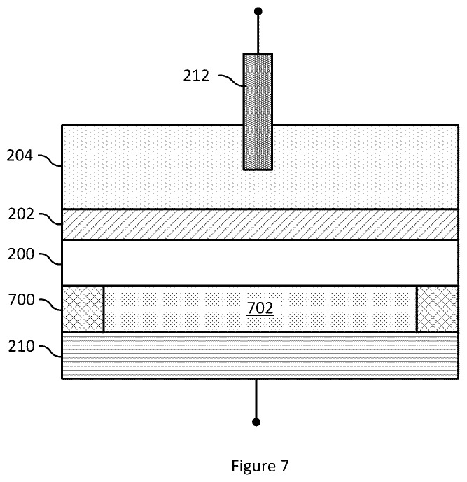

FIG. 7 shows an enlarged schematic view of a variation of the apparatus 20a with reference to FIG. 2A, in accordance with an embodiment. In some embodiments, FIG. 7 also represents an enlarged schematic view of a variation of the apparatus 20b with reference to FIG. 2B.

The embodiment differs from the prior embodiments by including an additional liquid electrolyte layer between the substrate 200 and the first electrode 210. The layer-to-be-etched 202 may be disposed over the substrate 200. A first liquid electrolyte layer 204 may be dispensed over the layer-to-be-etched 202 and serve as a charge carrier medium. The first electrode 210 may be coupled to the substrate 200 through a second liquid electrolyte layer 702.

The second liquid electrolyte layer 702 may comprise water, isopropyl alcohol, ammonium halides and carbonates in water that are less reactive with the substrate 200, but high enough conductivities for electrochemical measurements. The ammonium halides and carbonates may comprise ammonium chloride (NH₄Cl), ammonium fluoride (NH₄F), ammonium iodide (NH₄I), ammonium sulfate ((NH₄)₂SO₄), ammonium carbonate ((NH₄)₂CO₃), or ammonium bicarbonate ((NH₄) HCO₃). In some embodiments, non-aqueous solvents such as methanol, ethanol, isopropanol, acetone, ethyl acetate, acetonitrile, ketones, and dimethyl sulfoxide (DMSO) may be included to adjust the reactivity between the second liquid electrolyte layer 702 and the substrate 200. In some embodiments, the second liquid electrolyte layer 702 may comprise ionic liquids such as 1-ethyl-3-methylimidazolium dicyanamide, 1-ethyl-3-methylimdazolium thiocyanate, 1-ethyl-3-methylimidazolium tetrafluoroborate, 1-ethyl-3-methylimidazolium trifluoromethylsulfonate, or the like.

The second liquid electrolyte layer 702 may be sealed by a gasket 700 comprising silicone rubber, polytetrafluoroethylene (PTFE), or ethylene propylene diene monomer rubber (EPDM rubber). The gasket 700 may be ring shaped and enclose the liquid within the second liquid electrolyte layer 702 to prevent leakage.

The second electrode 212 may be coupled to the first liquid electrolyte layer 204 to complete the electrical circuit. The components in FIG. 7 may respectively comprise the materials, structures, and/or other components described above with reference to corresponding parts of FIGS. 2A-2B. The second liquid electrolyte layer 702 may prevent direct contact between the first electrode 210 and the substrate 200, thereby avoiding potential mechanical damage or contamination of the substrate 200 during impedance measurements. Moreover, it may provide a consistent separation distance, enhancing measurement accuracy. The composition of the second liquid electrolyte layer 702 may be tuned to provide extra flexibility of optimizing accuracy to meet specific requirements.

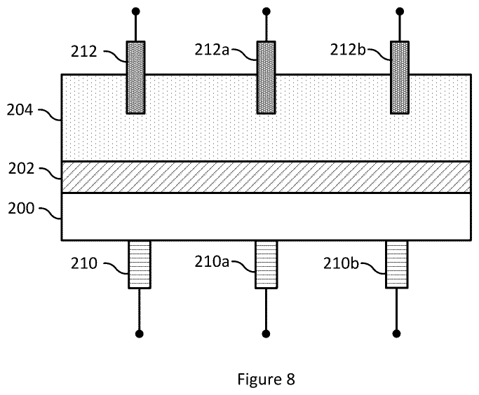

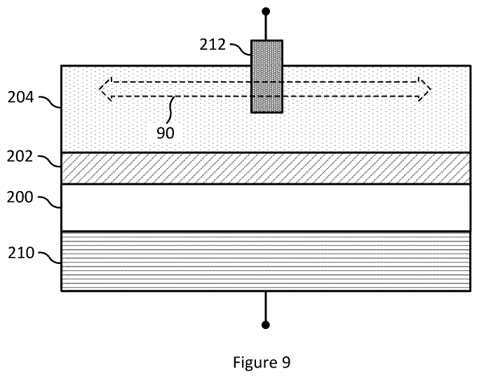

FIG. 8 is an enlarged schematic view of a variation of the apparatus 20a with reference to FIG. 2A, in accordance with an embodiment.

The embodiment differs from the prior embodiments by coupling additional first electrodes 210 to the substrate 200 and additional second electrodes 212 to the first liquid electrolyte layer 204. The layer-to-be-etched 202 may be disposed over the substrate 200. The first liquid electrolyte layer 204 may be dispensed over the layer-to-be-etched 202 and serve as a charge carrier medium. The first electrode 210 may be coupled to the substrate 200 and the second electrode 212 may be coupled to the first liquid electrolyte layer 204. The first electrode 210 and the second electrode 212 may be aligned to target at a first position of the layer-to-be-etched 202 for a local impedance measurement. A third electrode 210a may be coupled to the substrate 200 and a fourth electrode 212a may be coupled to the first liquid electrolyte layer 204. The third electrode 210a and the fourth electrode 212a may be aligned to target at a second position of the layer-to-be-etched 202 for another local impedance measurement. One or more of electrodes may be coupled to the layer-to-be-etched 202 and the first liquid electrolyte layer 204 for more local impedance measurements.

In some embodiments, a fifth electrode 210b may be coupled to the substrate 200 and a sixth electrode 212b may be coupled to the first liquid electrolyte layer 204. The fifth electrode 210b and the sixth electrode 212b may be aligned to target at a third position of the layer-to-be-etched 202 for an additional local impedance measurement. In some embodiments, the first, the second, the third, the fourth, the fifth, and the sixth electrodes 210, 212, 210a, 212a, 210b, and 212b may be positioned on only half side of the first liquid electrolyte layer 204 or the substrate 200. With the substrate 200 rotating around the center axis, this configuration allows for comprehensive radial measurements across the entire substrate. This arrangement optimizes the use of substrate space while ensuring complete measurement coverage, potentially leaving the other half of the substrate available for other processes or comparisons.

The first, the second, the third, the fourth, the fifth, and the sixth electrodes 210, 212, 210a, 212a, 210b, and 212b described above may comprise a diameter of 0.01 mm to 10 mm and comprise the materials, structures, and/or other components with reference to the electrodes of FIGS. 2A-2B. Each pair of electrodes may be controlled independently by the impedance spectroscope 208 to apply the alternating voltage and measure the responsive current. By capturing impedance data from each electrode pair, a radial thickness distribution profile of the layer-to-be-etched 202 may be obtained. This localized approach allows for greater precision in monitoring variations across different regions of the layer-to-be-etched 202. In response to identified thickness deviations, the dispensing arm 206 may adjust a delivery of wet etchant to specific positions, optimizing etching uniformity.

FIG. 9 is an enlarged schematic view of the apparatus 20b with reference to FIG. 2B, in accordance with an embodiment. In some embodiments, FIG. 9 also represents an enlarged schematic view of a variation of the apparatus 20a with reference to FIG. 2A.

The embodiment differs from the prior embodiments by featuring the second electrode 212, which can scan different positions within the electrolyte layer 204 during the etching process. The layer-to-be-etched 202 may be disposed over the substrate 200. The first liquid electrolyte layer 204 may be dispensed over the layer-to-be-etched 202 and serve as a charge carrier medium. The first electrode 210 may be coupled to the substrate 200 and the second electrode 212 may be coupled to the first liquid electrolyte layer 204. In some embodiments, the second electrode 212 may scan different positions within the first liquid electrolyte layer 204 along a direction 90. The second electrode 212 may comprise a diameter of 0.01 mm to 10 mm to measure a local current response. By scanning different positions, the radial distribution of the thickness of the layer-to-be-etched 202 may be obtained. In some embodiments, the second electrode 212 may only scan half side of the first liquid electrolyte layer 204. With the substrate 200 rotating around the center axis, this configuration allows for comprehensive radial measurements across the entire substrate. This arrangement optimizes the use of substrate space while ensuring complete measurement coverage, potentially leaving the other half of the substrate available for other processes or comparisons. In response to any identified thickness discrepancies, the dispensing arm 206 may adjust the delivery of wet etchant to specific positions, optimizing etching uniformity. The components in FIG. 9 may respectively comprise the materials, structures, and/or other components described above with reference to corresponding parts of FIGS. 2A-2B.

FIG. 10A is an enlarged schematic view of a variation of the apparatus 20a with reference to FIG. 2A, in accordance with an embodiment.

The embodiment differs from the prior embodiments by including an intermediate layer between the substrate 200 and the layer-to-be-etched 202. An intermediate layer 1000 may be disposed over the substrate 200. The intermediate layer 1000 may comprise group 3-5 semiconductors, metals, oxides, nitrides, polymers, or any solid-state materials. In various embodiments, the intermediate layer 1000 may comprise a plurality of layers including different material layers. The layer-to-be-etched 202 may be disposed over the intermediate layer 1000. The first liquid electrolyte layer 204 may be dispensed over the layer-to-be-etched 202 and serve as a charge carrier medium. The first electrode 210 may be coupled to the substrate 200 and the second electrode 212 may be coupled to the first liquid electrolyte layer 204. During the impedance measurement, the intermediate layer 1000 may introduce more data complexity due to additional resistance and capacitance.

Referring to FIG. 10B, a corresponding equivalent electrical circuit model with reference to FIG. 10A is illustrated, in accordance with an embodiment. With the incorporation of the intermediate layer 1000, the equivalent electrical circuit model may be represented by a series connection of five electrical elements E101-E105. Resistance R101 may represent the resistance of a first element E101 comprising the first liquid electrolyte layer 204.

Resistance R102 and capacitance C102 may collectively represent the impedance of a second element E102 comprising the interface between the first liquid electrolyte layer 204 and the layer-to-be-etched 202. This interface may have a resistive behavior (giving rise to the resistance R102) due to current flow and a capacitive behavior (giving rise to the capacitance C102) due to charge storage at the interface.

Resistance R103 and capacitance C103 may collectively represent the impedance of a third element E103 comprising the interface between the layer-to-be-etched 202 and the intermediate layer 1000. This interface may also have a resistive behavior (giving rise to the resistance R103) due to electron flow and a capacitive behavior (giving rise to the capacitance C103) due to charge storage at the interface.

Resistance R104 and capacitance C104 may collectively represent the impedance of a fourth element E104 comprising the interface between the intermediate layer 1000 and the substrate 200. This interface may also have a resistive behavior (giving rise to the resistance R104) due to electron flow and a capacitive behavior (giving rise to the capacitance C104) due to charge storage at the interface. Resistance R105 may represent the resistance of a fifth element E105, comprising the substrate 200.

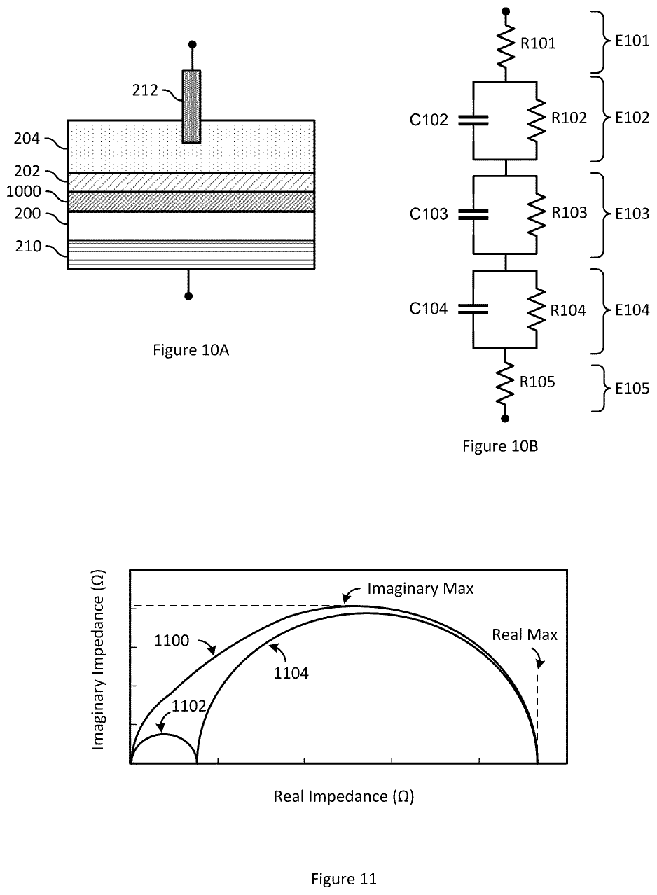

FIG. 11 presents a schematic Nyquist plot reflecting the equivalent electrical circuit model with reference to FIG. 10B, in accordance with an embodiment. A total impedance curve 1100 illustrates the total impedance of the circuit responding to the alternating voltage. An imaginary max and a real max may be obtained from the total impedance curve 1100, which represent the maximum imaginary impedance and the maximum real impedance from the electrical circuit, respectively. The total impedance curve 1100 may be fitted with a first semicircular curve 1102 and a second semicircular curve 1104. In some embodiments, the first semicircular curve 1102 may represent the impedance of the intermediate layer 1000 comprising silicon oxide, while the second semicircular curve 1104 may represent the impedance of the layer-to-be-etched 202 comprising silicon nitride. Due to higher dielectric constant of silicon nitride than silicon oxide, the second semicircular curve 1104 may have larger radius than the first semicircular cure 1102. The ability to distinguish the impedances of different layers shows the advantage of impedance measurement for accurate layer thickness measurement. The impedance of each electrical element in FIG. 10B may be obtained from fitting the Nyquist plot with the equivalent electrical circuit model.

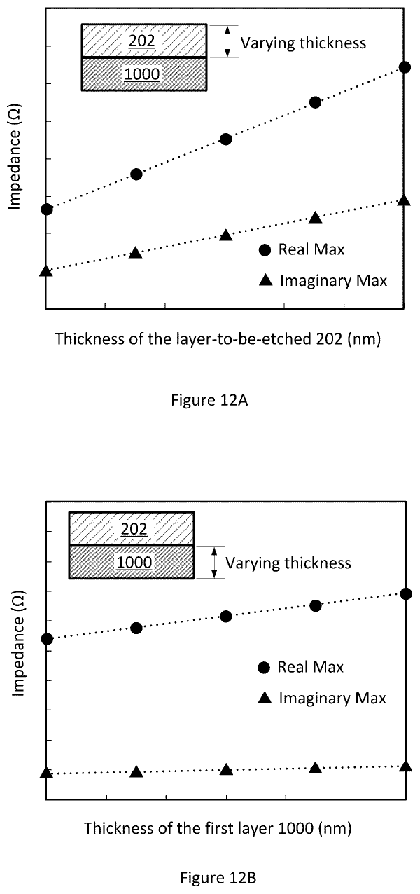

FIG. 12A shows the impedance changes in response to the thickness change of the layer-to-be-etched 202, in accordance with some embodiments. The thickness of the layer-to-be-etched 202 may be varying while the thickness of the intermediate layer 1000 may be fixed. When the thickness of the layer-to-be-etched 202 increases, both the maximum real (labeled Real Max) and maximum imaginary impedance (labeled Imaginary Max) values increase and can be linearly fitted, demonstrating a clear correlation. This linear fit may serve as the reference in practical applications. By measuring impedance during the etching process, the thickness of the layer-to-be-etched 202 can be accurately determined using this established correlation. In other embodiments, the thickness of the intermediate layer 1000 may be varying while the thickness of the layer-to-be-etched 202 may be fixed.

FIG. 12B shows the impedance changes in response to the thickness change of the intermediate layer 1000, in accordance with some embodiments. The thickness of the intermediate layer 1000 may be varying while the thickness of the layer-to-be-etched 202 may be fixed. When the thickness of the intermediate layer 1000 increases, the real max may increase while the imaginary max may have minimal change. Both data can be linearly fitted to the thickness, illustrating a clear correlation. By collecting the impedance data during etching process, the corresponding thickness of the intermediate layer 1000 may be estimated by referencing with this linear fit.

The linear relationships illustrated in FIG. 12A and FIG. 12B may address a challenge faced in in-situ optical thickness measurements, where the optical signal varies sinusoidally with layer thickness due to the wave nature of light. In contrast, the impedance-based approach demonstrates a more straightforward, linear relationship with layer thickness. A comprehensive database comprising the impedance data from various combinations of layer thicknesses and material compositions may be developed. This database may serve as a reference, enabling real-time determination of the thickness profile during the etching process.

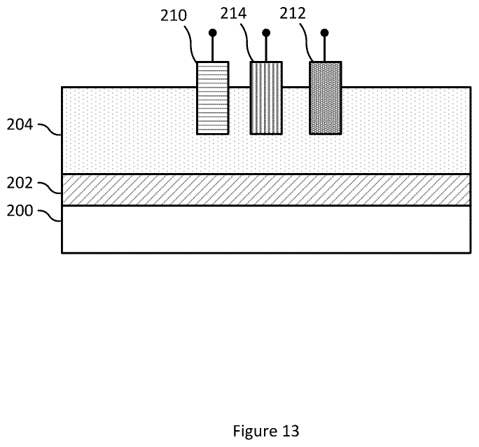

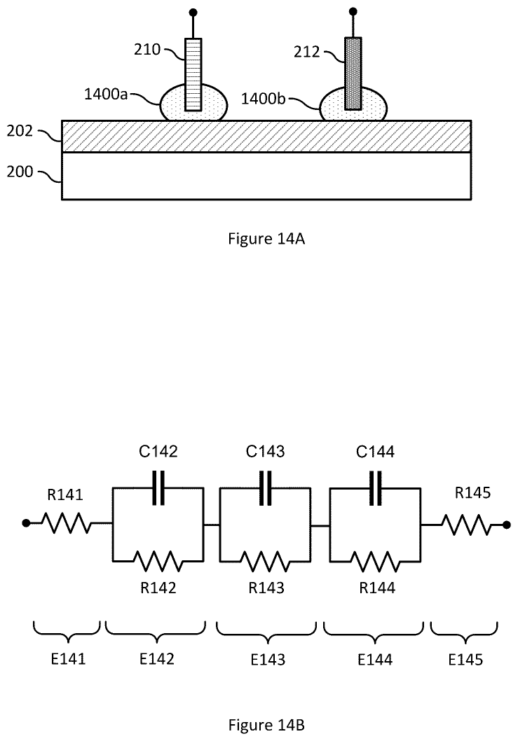

FIG. 13 shows an enlarged schematic view of a variation of the apparatus 20a illustrated in FIG. 2A, in accordance with an embodiment.

The embodiment differs from the prior embodiments by disconnecting the first electrode 210 from the substrate 200, while coupling the first, the second, and the third electrodes 210, 212, and 214 to the first liquid electrolyte layer 204. The layer-to-be-etched 202 may be disposed over the substrate 200. The first liquid electrolyte layer 204 may be dispensed over the layer-to-be-etched 202 and serve as a charge carrier medium.

The first electrode 210, the second electrode 212, the third electrode 214 may be coupled to the first liquid electrolyte layer 204 and isolated from each other to avoid direct contact. The first electrode 210, the second electrode 212, and the third electrode 214 may serve as the working electrode, the counter electrode, and the reference electrode, respectively. The alternating voltage may be applied between the first electrode 210 and the second electrode 212, directing current primarily through the first electrode 210, the first liquid electrolyte layer 204, and the second electrode 212. With the reference potential provided by the third electrode 214, the voltage between the first electrode 210 and the third electrode 214 enables precise measurement of changes in electrochemical potential. This may allow for accurate determination of solution conductivity and composition within the first liquid electrolyte layer 204. To minimize current flow and prevent interference with the reference potential measurement, the distance between the third electrode 214 and the second electrode 212 may be adequately maintained. The optimal distance may be determined by adjusting the position of the third electrode 214 until a stable reference potential is achieved. In some embodiments, the distance may be 1 cm to 5 cm for accurate potential measurement.

In some embodiments, the first liquid electrolyte layer 204 may comprise the wet etchant during the etching process. Therefore, the method may be used to real-time monitor and assess the wet etchant continuously, ensuring that any deviations in chemical composition are promptly identified and corrected, leading to stable etching rate and uniform etching. The components in FIG. 13 may respectively comprise the materials, structures, and/or other components described above with reference to corresponding parts of FIGS. 2A-2B.

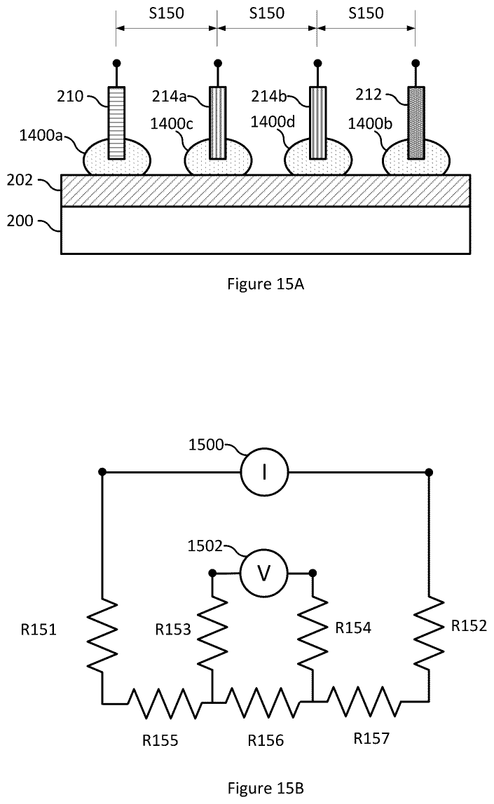

FIG. 14A shows an enlarged schematic view of a variation of the apparatus 20a illustrated in FIG. 2A, in accordance with an embodiment.

The embodiment differs from the prior embodiments by including liquid electrolyte droplet as charge carrier medium during impedance measurement. The layer-to-be-etched 202 may be disposed over the substrate 200. A first liquid electrolyte droplet 1400a may be dispensed over the layer-to-be-etched 202 and serve as a first charge carrier medium. The first electrode 210 may be coupled to the first liquid electrolyte droplet 1400a. A second liquid electrolyte droplet 1400b may be dispensed over the layer-to-be-etched 202 and serve as a second charge carrier medium. The first and the second liquid electrolyte droplets 1400a and 1400b may be isolated from direct contact and comprise water, isopropyl alcohol, ammonium halides and carbonates in water that are less reactive with the layer-to-be-etched 202, but high enough conductivities for electrochemical measurements. The ammonium halides and carbonates may comprise ammonium chloride (NH₄Cl), ammonium fluoride (NH₄F), ammonium iodide (NH₄I), ammonium sulfate ((NH₄)₂SO₄), ammonium carbonate ((NH₄)₂CO₃), or ammonium bicarbonate ((NH₄) HCO₃).

In some embodiments, the first and the second liquid electrolyte droplets 1400a and 1400b may further comprise non-aqueous solvents such as methanol, ethanol, isopropanol, acetone, ethyl acetate, acetonitrile, ketones, and dimethyl sulfoxide (DMSO) to reduce the reactivity between the layer-to-be-etched 202 and the first and the second liquid electrolyte droplets 1400a and 1400b. In one example, tetramethylammonium hydroxide (TMAH) may be mixed with methanol. In another example, hydrochloric acid (HCl), hydrofluoric acid (HF), hydrobromic acid (HBr), or hydroiodic acid (HI) may be mixed with methanol. In another example, ammonium chloride (NH₄Cl) may be mixed with acetone or ethyl acetate. In another example, ammonium tetrafluoroborate (NH₄BF₄) may be mixed with non-aqueous solvents such as methanol, isopropanol, ethanol, or the like.

In some embodiments, the first and the second liquid electrolyte droplets 1400a and 1400b may comprise ionic liquids such as 1-ethyl-3-methylimidazolium dicyanamide, 1-ethyl-3-methylimdazolium thiocyanate, 1-ethyl-3-methylimidazolium tetrafluoroborate, 1-ethyl-3-methylimidazolium trifluoromethylsulfonate, or the like. Due to negligible vapor pressures, the ionic liquids may maintain a constant droplet size for the first and the second liquid electrolyte droplets 1400a and 1400b, enabling reliable impedance measurement of the layer-to-be-etched 202. Moreover, the contact angles of ionic liquids on different surfaces can be adjusted by controlling the cation and anion species or applying high voltages, allowing for excellent adaptability to different materials of the layer-to-be-etched 202.

The first and the second liquid electrolyte droplets 1400a and 1400b may be removed before the wet etchant for etching process is dispensed over the layer-to-be-etched 202. The components in FIG. 14A may respectively comprise the materials, structures, and/or other components described above with reference to corresponding parts of FIGS. 2A-2B.

In some embodiments, the alternating voltage at different frequencies may be applied between the first electrode 210 (serving as the working electrode) and the second electrode 212 (serving as the counter electrode). The electrical circuit may be completed with current flowing through the first electrode 210, the first liquid electrolyte droplet 1400a, the layer-to-be-etched 202, the second liquid electrolyte droplet 1400b, and the second electrode 212.

In some embodiments, one or more of isolated liquid electrolyte droplets may be dispensed over the layer-to-be-etched 202 with each being coupled to one of the first electrode 210 and the second electrode 212. These additional electrodes may enable impedance measurement at different locations to obtain the radial thickness distribution of the layer-to-be-etched 202. Due to the small size of liquid droplet in millimeter scale, the method allows for localized measurements that can easily adapt to varied layer geometries.

FIG. 14B illustrates an equivalent electrical circuit model with reference to FIG. 14A, in accordance with an embodiment. The electrical circuit may be represented by a series connection of five electrical elements E141-E145. Resistance R141 may represent the resistance of a first element E141 comprising the first liquid electrolyte droplet 1400a.

Resistance R142 and capacitance C142 may collectively represent the impedance of a second element E142 comprising the interface between the first liquid electrolyte droplet 1400a and the layer-to-be-etched 202. This interface may have a resistive behavior (giving rise to the resistance R142) due to current flow and a capacitive behavior (giving rise to the capacitance C142) due to charge storage at the interface.

Resistance R143 and capacitance C143 may collectively represent the impedance of a third element E143 comprising the interface between the layer-to-be-etched 202 and the substrate 200. This interface may also have a resistive behavior (giving rise to the resistance R143) due to electron flow and a capacitive behavior (giving rise to capacitance the C143) due to charge storage at the interface.

Resistance R144 and capacitance C144 may collectively represent the impedance of a fourth element E144 comprising the interface between the second liquid electrolyte droplet 1400b and the layer-to-be-etched 202. This interface may also have a resistive behavior (giving rise to the resistance R144) due to electron flow and a capacitive behavior (giving rise to the capacitance C144) due to charge storage at the interface.

Resistance R145 may represent the resistance of a fifth element E145, comprising the second liquid electrolyte 1400b. By fitting the impedance data from the Nyquist plot with this electrical circuit model using Equation 1, the impedance of the layer-to-be-etched 202, in relation to its thickness, may be determined.

Now refer to FIG. 15A, an enlarged schematic view of a variation of the apparatus 20a illustrated in FIG. 2A is illustrated, in accordance with an embodiment.

The embodiment differs from the prior embodiments by including four electrodes, enabling a four-point probe measurement to determine the resistance of the layer-to-be-etched 202 disposed over the substrate 200. A first liquid electrolyte droplet 1400a may be dispensed over the layer-to-be-etched 202 and serve as a first charge carrier medium. The first electrode 210 may be coupled to the first liquid electrolyte droplet 1400a. A second liquid electrolyte droplet 1400b may be dispensed over the layer-to-be-etched 202 and serve as a second charge carrier medium. The second electrode 212 may be coupled to the second liquid electrolyte droplet 1400b. In some embodiments, the first electrode 210 may be the working electrode comprising platinum, gold, glassy carbon, or carbon paste, while the second electrode 212 may be the counter electrode comprising platinum, graphite, or gold. The first and the second electrodes 210 and 212 may provide a current path in the four-point probe measurement.

A third liquid electrolyte droplet 1400c may be dispensed over the layer-to-be-etched 202 and serve as a third charge carrier medium. A third electrode 214a may be coupled to the third liquid electrolyte droplet 1400c. A fourth liquid electrolyte droplet 1400d may be dispensed over the layer-to-be-etched 202 and serve as a fourth charge carrier medium. A fourth electrode 214b may be coupled to the fourth liquid electrolyte droplet 1400d. In some embodiments, the third and the fourth electrodes 214a and 214b may be reference electrodes comprising silver/silver chloride (Ag/AgCl), calomel, or mercury/mercury sulfate. The third and the fourth electrodes 214a and 214b may provide a voltage measurement path.

In some embodiments, the first, the second, the third, and the fourth electrodes 210, 212, 214a, and 214b may be isolated from each other. Distance S150 may represent the distance between the first electrode 210 and the third electrode 214a. The distance between the third electrode 214a and the fourth electrode 214b, and the distance between the fourth electrode 214b and the second electrode 212 may be same as the distance S150.

The first, the second, the third, and the forth liquid electrolyte droplets 1400a, 1400b, 1400c, and 1400d may comprise the materials described above with reference to the liquid electrolyte droplet in FIG. 14A.

This four-point probe arrangement may allow for precise separation of the current path from the voltage measurement path. By applying current between the first electrode 210 and the second electrode 212, the arrangement ensures that contact resistance or variations in electrode contact do not impact the voltage measurements taken between the third electrode 214a and the fourth electrode 214b, thereby enhancing the accuracy and reliability of the impedance measurement. Moreover, the first, the second, the third, and the forth liquid electrolyte droplets 1400a, 1400b, 1400c, and 1400d may help prevent direct contacts between the layer-to-be-etched 202 and the first, the second, the third, and the fourth electrodes 210, 212, 214a, and 214b and, thereby avoiding potential mechanical damage or contamination.

FIG. 15B illustrates an equivalent electrical circuit model with reference to FIG. 15A, in accordance with an embodiment. An alternating current with low frequency may be provided by a current source 1500 between the first and second electrodes 210 and 212. The voltage between the third and the fourth electrodes 214a and 214b may be measured with a voltmeter 1502. The current source 1500 and the voltmeter 1502 may be part of the impedance spectroscope 208. A low-frequency measurement may result in high capacitive reactance of each capacitive element in the equivalent electrical circuit, acting as an open circuit. This may allow the impedance measurement to focus on the resistive behavior, ensuring a more straightforward analysis of the resistance of the layer-to-be-etched 202. In addition, the low-frequency measurement may reduce the influence of parasitic inductances and capacitances, providing a clearer indication of the actual resistive behavior. The equivalent circuit is thereby modeled by a series of resistors.

Resistance R151, resistance R152, resistance R153 and resistance R154 may represent the resistances associated with the first, the second, the third, and the fourth liquid electrolyte droplets 1400a, 1400b, 1400c and 1400d, respectively. Resistance R155 may represent the resistance of the layer-to-be-etched 202 in a region between the first electrode 210 and the third electrode 214a. Resistance R156 may represent the resistance of the layer-to-be-etched 202 in a region between the third electrode 214a and the fourth electrode 214b. Resistance R157 may represent the resistance of the layer-to-be-etched 202 in a region between the fourth electrode 214b and the second electrode 212.

With current supplied by the current source 1500, the voltmeter 1502 may measure voltage drop across the third electrode 214a and the fourth electrode 214b, allowing a direct way to obtain the resistance of the layer-to-be-etched 202 (resistance R156). The four-point probe measurement may be particularly advantageous when the layer-to-be-etched 202 possesses higher conductivity than the substrate 200 that the current flow through the substrate 200 is minimal. This setup allows for precise impedance determination, facilitating a measurement of material thickness and enabling optimized etching processes.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for an etching process comprising:
dispensing a liquid electrolyte layer over a layer-to-be-etched disposed over a substrate;
coupling a first electrode to the substrate and a second electrode to the liquid electrolyte layer;
applying an alternating voltage at different frequencies between the first and the second electrodes;
collecting impedance data between the first and the second electrodes in response to the alternating voltage; and
etching the layer-to-be-etched with an etching parameter selected based on the impedance data.

2. The method of claim 1, further comprising:
obtaining a distribution of a thickness of the layer-to-be-etched across the substrate from the impedance data;
obtaining a rate of etching of the layer-to-be-etched by analyzing the distribution of the thickness; and
obtaining the etching parameter based on the rate of etching the layer-to-be-etched.

3. The method of claim 1, further comprising removing the liquid electrolyte layer before the etching.

4. The method of claim 1, further comprising obtaining a composition of the liquid electrolyte layer by analyzing the impedance data.

5. The method of claim 1, wherein the liquid electrolyte layer comprises water, isopropyl alcohol, methanol, ethanol, isopropanol, acetone, ethyl acetate, acetonitrile, ketones, and dimethyl sulfoxide (DMSO), ammonium halides, ammonium carbonates, tetramethylammonium hydroxide (TMAH), ammonium tetrafluoroborate (NH₄BF₄), hydrochloric acid (HCl), hydrofluoric acid (HF), hydrobromic acid (HBr), or hydroiodic acid (HI), or ionic liquid.

6. The method of claim 1, wherein the first electrode comprises platinum, gold, glassy carbon, or carbon paste, and wherein the second electrode comprises platinum, gold, or graphite.

7. The method of claim 1, wherein the etching parameter comprises wet etchant composition, etching duration, etching chamber temperature, or dispensing arm position of a dispensing arm during the dispensing of the liquid electrolyte layer.

8. The method of claim 1, further comprising:
coupling a third electrode to the liquid electrolyte layer, the third electrode comprising silver/silver chloride (Ag/AgCl), calomel, or mercury/mercury sulfate;
applying a reference potential to the third electrode; and
collecting voltage information from the third electrode in response to the alternating voltage.

9. A method for an etching process comprising:
dispensing a first liquid electrolyte droplet over a layer-to-be-etched disposed over a substrate;
coupling a first electrode to the first liquid electrolyte droplet;
dispensing a second liquid electrolyte droplet over the layer-to-be-etched, wherein the second liquid electrolyte droplet remains isolated from the first liquid electrolyte droplet;
coupling a second electrode to the second liquid electrolyte droplet;
applying an alternating voltage at different frequencies between the first and the second electrodes;
collecting impedance data between the first and the second electrodes in response to the alternating voltage; and
etching the layer-to-be-etched with an etching parameter selected based on the impedance data.

10. The method of claim 9, further comprising:
obtaining a distribution of a thickness of the layer-to-be-etched across the substrate from the impedance data;
obtaining a rate of etching of the layer-to-be-etched by analyzing the distribution of the thickness; and
obtaining the etching parameter based on the rate of etching the layer-to-be-etched.

11. The method of claim 9, further comprising removing the first and the second liquid electrolyte droplets before the etching.

12. The method of claim 9, wherein the first liquid electrolyte droplet comprises water, isopropyl alcohol, methanol, ethanol, isopropanol, acetone, ethyl acetate, acetonitrile, ketones, and dimethyl sulfoxide (DMSO), ammonium halides, ammonium carbonates, tetramethylammonium hydroxide (TMAH), ammonium tetrafluoroborate (NH₄BF₄), hydrochloric acid (HCl), hydrofluoric acid (HF), hydrobromic acid (HBr), or hydroiodic acid (HI), or ionic liquid.

13. The method of claim 9, wherein the first electrode comprises platinum, gold, glassy carbon, or carbon paste, and wherein the second electrode comprises platinum, gold, or graphite.

14. The method of claim 9, wherein the etching parameter comprises wet etchant composition, etching duration, etching chamber temperature, or dispensing arm position of a dispensing arm during the dispensing of the liquid electrolyte layer.

15. The method of claim 9, further comprising:
dispensing a third liquid electrolyte droplet over the layer-to-be-etched;
coupling a third electrode to the third liquid electrolyte droplet, the third electrode comprising silver/silver chloride (Ag/AgCl), calomel, or mercury/mercury sulfate; and
collecting voltage information from the third electrode.

16. An etching apparatus comprising:
an etch chamber;
a dispensing arm disposed within the etch chamber, the dispensing arm configured to dispense a first liquid electrolyte layer over a layer-to-be-etched of a substrate;
a first electrode configured to be coupled to the substrate;
a second electrode configured to be coupled to the first liquid electrolyte layer; and
an impedance spectroscope coupled to the first and the second electrodes, the impedance spectroscope being configured to apply an alternating voltage at different frequencies between the first and the second electrodes to collect impedance data.

17. The apparatus of claim 16, wherein the dispensing arm is configured to move around the substrate to dispense the liquid electrolyte layer over the layer-to-be-etched at different positions.

18. The apparatus of claim 16, further comprising a vacuum chuck for supporting the substrate.

19. The apparatus of claim 16, wherein the second electrode is configured to scan different positions within the first liquid electrolyte layer to obtain a radial distribution of a thickness of the layer-to-be-etched.

20. The apparatus of claim 16, further comprising:
a third electrode configured to be coupled to the substrate;
a fourth electrode configured to be coupled to the first liquid electrolyte layer; and
the impedance spectroscope coupled to the third and the fourth electrodes, the impedance spectroscope being configured to apply an alternating voltage at different frequencies between the third and the fourth electrodes to collect impedance data.
